(19) United States
(12) Patent Application Publication
(10) Pub. No.: US 2025/0246512 A1
(43) Pub. Date: Jul. 31, 2025

(54) POWER MODULE, METHOD OF MANUFACTURING POWER MODULE, AND POWER CONVERSION DEVICE

(71) Applicant: Mitsubishi Electric Corporation, Tokyo (JP)

(72) Inventors: Tsuyoshi HAMADA, Tokyo (JP); Masaki GOTO, Tokyo (JP); Hayato TERADA, Tokyo (JP); Hodaka ROKUBUICHI, Tokyo (JP); Wakana MASUDA, Tokyo (JP); Yasuyuki SANDA, Tokyo (JP); Tatsushi MORISADA, Tokyo (JP)

(73) Assignee: Mitsubishi Electric Corporation, Tokyo (JP)

(21) Appl. No.: 18/856,188

(22) PCT Filed: Apr. 27, 2023
(86) PCT No.: PCT/JP2023/016649

§ 371 Date: Oct. 11, 2024

(30) Foreign Application Priority Data
May 16, 2022 (JP) 2022-079918

(51) Int. Cl. H01L 23/40; H01L 21/48; H01L 23/31; H01L 23/367

(52) U.S. Cl. CPC H01L 23/4006; H01L 21/4882; H01L 23/3672; H01L 23/3107

(57) ABSTRACT

A power module includes: a semiconductor chip; a lead frame mounting the semiconductor chip on one surface; a module base on one surface of which the lead frame is disposed; a main terminal being a part of the lead frame; a molding portion sealing the semiconductor chip, the lead frame, and the module base; a heat sink including a base portion integrated with another surface of the module base exposed from the molding portion, and radiating fins; a bus bar connected to a first main surface of the main terminal or a second main surface opposite to the first main surface; and a terminal block fixed on the base portion of the heat sink and disposed between the base portion and the main terminal or the bus bar, wherein the second main surface faces the heat sink, and the first main surface faces an opposite side of the heat sink.

### TECHNICAL FIELD

The present disclosure relates to a power module, a method of manufacturing the power module, and a power conversion device.

### BACKGROUND ART

For example, Patent Document 1 discloses a heat sink integrated power module including a power module unit, a fin base, and radiating fins. The power module unit includes a module base, power semiconductor elements mounted on the module base, and a mold resin sealing the power semiconductor elements. The fin base includes a heat radiation diffusion portion to which the radiating fins are attached, and a base portion formed on the heat radiation diffusion portion and to which the module base is bonded. The module base includes a first recess-protrusion portion, and the base portion includes a second recess-protrusion portion fitted into the first recess-protrusion portion.

### PRIOR ART DOCUMENT

### Patent Document

Patent Document 1: Japanese Patent No. 675904

### SUMMARY

### Problem to be Solved by the Invention

The larger the current flowing through a power module is, the larger the current flowing through a main terminal is. Thus, a temperature rise in the main terminal increases. Connecting a bus bar (an external terminal) to the main terminal has widely and commonly been used to suppress the temperature rise in the main terminal.

The technology described in Patent Document 1, however, does not include a structure for connecting the bus bar to the main terminal. Thus, there has been apprehension about an increase in the temperature rise in the main terminal.

Thereby, an object of the present disclosure is to provide a technology capable of suppressing the temperature rise in the main terminal by connecting an external terminal to the main terminal in a heat sink integrated power module.

### Means to Solve the Problem

A power module according to the present disclosure includes: a semiconductor element; a frame on one surface of which the semiconductor element is mounted; a module base on one surface of which the frame is disposed; a main terminal that is a part of the frame; a molding portion sealing the semiconductor element, the frame, and the module base such that the main terminal is exposed; a heat sink including a base portion integrated with an other surface of the module base which is exposed from the molding portion, and a plurality of radiating fins protruding on an opposite side of the module base with respect to the base portion; an external terminal connected to a first main surface of the main terminal or a second main surface on an opposite side of the first main surface; and a displacement-controlling structural component fixed on the base portion of the heat sink and disposed between the base portion and the main terminal or the external terminal, wherein the second main surface of the main terminal faces the heat sink, and the first main surface of the main terminal faces an opposite side of the heat sink.

### Effects of the Invention

Since the present disclosure does not require terminal-shaping machining on the first main surface and the second main surface of the main terminal, the area of the first main surface and the second main surface can be increased. This enables connection of an external terminal to the main terminal in a heat sink integrated power module. Thus, the temperature rise in the main terminal can be suppressed.

The objects, features, aspects, and advantages of the present disclosure will become more apparent from the following detailed description and the accompanying drawings.

### BRIEF DESCRIPTION OF DRAWINGS

FIG. 1 is a cross-sectional view of a power module according to Embodiment 1.

FIG. 2 is a top view of the power module according to Embodiment 1.

FIG. 3 is a top view of the power module according to a modification of Embodiment 1.

FIG. 4 is a cross-sectional view illustrating a connection between a main terminal and a bus bar which are included in the power module according to a modification of Embodiment 1.

FIG. 5 is a top view of the power module according to a modification of Embodiment 1.

FIG. 6 is a top view of the power module according to a modification of Embodiment 1.

FIG. 7 is a cross-sectional view illustrating a screwing connection between the main terminal and the bus bar which are included in the power module according to a modification of Embodiment 1.

FIG. 8 is a cross-sectional view illustrating screwing connections between main terminals and bus bars which are included in the power module according to the modification of Embodiment 1.

FIG. 9 is a cross-sectional view illustrating a screwing connection between the main terminal and a nut-inserted bus bar which are included in the power module according to a modification of Embodiment 1.

FIG. 10 is a cross-sectional view illustrating a screwing connection between a nut-inserted main terminal and the bus bar which are included in the power module according to a modification of Embodiment 1.

FIG. 11 is a cross-sectional view illustrating a screwing connection between the main terminal and the bus bar in which a screwing auxiliary component included in the power module according to a modification of Embodiment 1 is disposed.

FIG. 12 is a cross-sectional view illustrating a position relationship between the main terminal and the screwing auxiliary component which are included in the power module according to a modification of Embodiment 1.

FIG. 13 is a cross-sectional view illustrating a position relationship between the main terminal and an elasticity-function screwing auxiliary component which are included in the power module according to a modification of Embodiment 1.

FIG. 14 is a cross-sectional view illustrating a soldering connection between the main terminal and the bus bar which are included in the power module according to a modification of Embodiment 1.

FIG. 15 is a cross-sectional view illustrating a welding connection between the main terminal and the bus bar which are included in the power module according to a modification of Embodiment 1.

FIG. 16 is a cross-sectional view illustrating a crimping connection between the main terminal and the bus bar which are included in the power module according to a modification of Embodiment 1.

FIG. 17 is a cross-sectional view of the power module according to a modification of Embodiment 1.

FIG. 18 is a cross-sectional view of the power module according to a modification of Embodiment 1.

FIG. 19 is a cross-sectional view of the power module according to a modification of Embodiment 1.

FIG. 20 is a cross-sectional view of a power module according to Embodiment 2.

FIG. 21 is a top view of the power module according to Embodiment 2.

FIG. 22 is a cross-sectional view illustrating a screwing connection between a terminal block and a heat sink which are included in the power module according to Embodiment 2.

FIG. 23 is a cross-sectional view illustrating a soldering connection between the terminal block and the heat sink which are included in the power module according to a modification of Embodiment 2.

FIG. 24 is a cross-sectional view illustrating a welding connection between the terminal block and the heat sink which are included in the power module according to a modification of Embodiment 2.

FIG. 25 is a cross-sectional view illustrating a crimping connection between the terminal block and the heat sink which are included in the power module according to a modification of Embodiment 2.

FIG. 26 is a cross-sectional view illustrating a screwing connection between the main terminal and the bus bar which are included in the power module according to a modification of Embodiment 2.

FIG. 27 is a cross-sectional view illustrating a soldering connection between the main terminal and the bus bar which are included in the power module according to a modification of Embodiment 2.

FIG. 28 is a cross-sectional view illustrating a welding connection between the main terminal and the bus bar which are included in the power module according to a modification of Embodiment 2.

FIG. 29 is a cross-sectional view illustrating a crimping connection between the main terminal and the bus bar which are included in the power module according to a modification of Embodiment 2.

FIG. 30 is a cross-sectional view illustrating, using a nut-inserted main terminal or the nut-inserted bus bar included in the power module according to a modification of Embodiment 2, a screwing connection between the main terminal and the bus bar.

FIG. 31 is a cross-sectional view illustrating the placement of the terminal block with a positioning structure which is included in the power module according to a modification of Embodiment 2.

FIG. 32 illustrates cross-sectional views, a side view, and top views of the placement of the terminal block with the positioning structure which is included in the power module according to a modification of Embodiment 2.

FIG. 33 is a cross-sectional view illustrating a clearance between the main terminal and the terminal block which are included in the power module according to a modification of Embodiment 2.

FIG. 34 is a cross-sectional view illustrating a screwing connection between the main terminal and the bus bar in the presence of a clearance between the main terminal and the terminal block which are included in the power module according to a modification of Embodiment 2.

FIG. 35 is a cross-sectional view illustrating, when an elasticity-function terminal block included in the power module according to a modification of Embodiment 2 is used, a clearance between the main terminal and the terminal block.

FIG. 36 is a cross-sectional view illustrating a screwing connection between the main terminal, the bus bar, and the terminal block which are included in the power module according to Embodiment 3.

FIG. 37 is a cross-sectional view illustrating soldering connections between the main terminal, the bus bar, and the terminal block which are included in the power module according to Embodiment 3.

FIG. 38 is a cross-sectional view illustrating welding connections between the main terminal, the bus bar, and the terminal block which are included in the power module according to Embodiment 3.

FIG. 39 is a cross-sectional view illustrating a crimping connection between the main terminal, the bus bar, and the terminal block which are included in the power module according to Embodiment 3.

FIG. 40 is a cross-sectional view illustrating the terminal block including a nut fall-off proof metal component which is included in the power module according to Embodiment 3.

FIG. 41 is a cross-sectional view illustrating a state of the power module according to Embodiment 3 during product use.

FIG. 42 is a cross-sectional view of a typical power module during product use.

FIG. 43 is a cross-sectional view illustrating a clearance between the main terminal and the terminal block which are included in the power module according to Embodiment 3.

FIG. 44 is a cross-sectional view illustrating a screwing connection between the main terminal, the bus bar, and the terminal block in the presence of a clearance between the main terminal and the terminal block which are included in the power module according to Embodiment 3.

FIG. 45 is a cross-sectional view illustrating, when an elasticity-function terminal block included in the power module according to a modification of Embodiment 3 is used, a clearance between the main terminal and the terminal block.

FIG. 46 is a block diagram illustrating a configuration of a power conversion system using the power conversion device according to Embodiment 4.

### DESCRIPTION OF EMBODIMENTS

### Embodiment 1

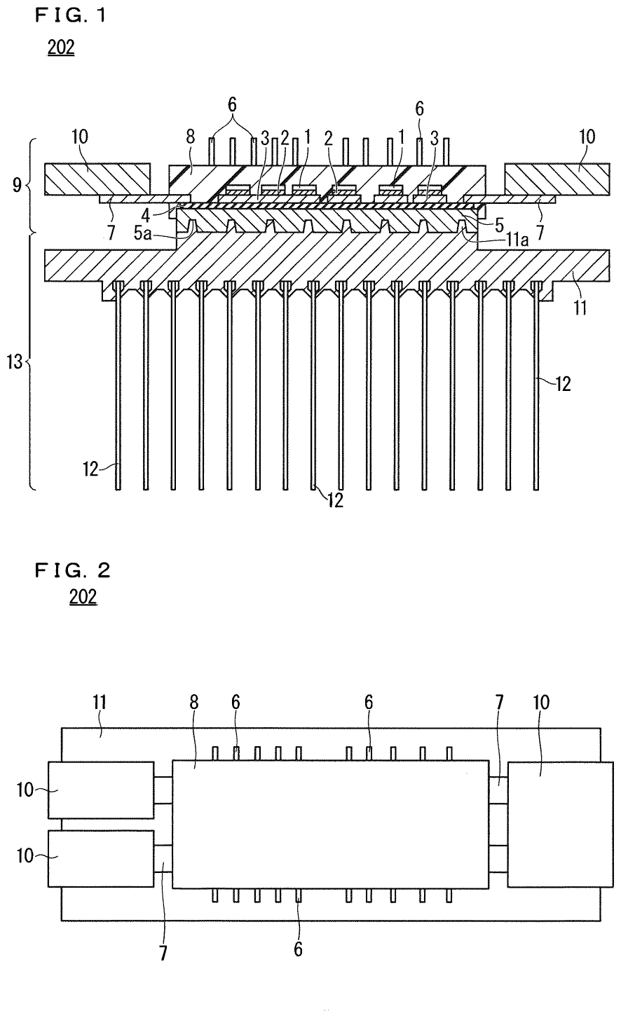

Embodiment 1 will be described with reference to drawings. FIG. 1 is a cross-sectional view of a power module 202 according to Embodiment 1. FIG. 2 is a top view of the power module 202 according to Embodiment 1.

As illustrated in FIGS. 1 and 2, the power module 202 is a heat sink integrated power module, and includes a power module unit 9 and a heat sink 13. The power module unit 9 includes a plurality of semiconductor chips 1 (semiconductor elements), a lead frame 3 (a frame), an insulation sheet 4, a module base 5, a molding portion 8, and a plurality of bus bars 10 (external terminals).

The plurality of semiconductor chips 1 is mounted on an upper surface (one surface) of the lead frame 3. The lead frame 3 is disposed through the insulation sheet 4 adhering to an upper surface (one surface) of the module base 5. The molding portion 8 is made of a mold resin, and seals the semiconductor chips 1, the lead frame 3, the insulation sheet 4, and the module base 5 such that the main terminals 7 that is a part of the lead frame 3, and a lower surface (another surface) of the module base 5 are exposed.

The heat sink 13 includes a base portion 11 integrated with the lower surface (another surface) of the module base 5, and a plurality of radiating fins 12 protruding below the base portion 11 (on the opposite side of the module base 5). A plurality of recessed fitting portions 5a is formed on the lower surface (another surface) of the module base 5. Furthermore, a plurality of protruding fitted portions 11a into which the fitting portions 5a can be fitted is formed on an upper surface of a portion of the base portion 11 except its perimeter (a surface closer to the module base 5). Fitting the fitting portions 5a into the fitted portions 11a integrates the module base 5 and the heat sink 13. The fitting portions 5a and the fitted portions 11a may be consecutively or intermittently formed on the module base 5 and the base portion 11, respectively, in a depth direction.

After molding, control terminals 6 and the main terminals 7 that are part of the lead frame 3 are formed by terminal-shaping molding. The terminal-shaping molding is not essential but can be omitted.

Next, the main terminals 7 and the control terminals 6 will be described. The main terminals 7 and the control terminals 6 are part of the lead frame 3, and are connected to the semiconductor chips 1 inside the molding portion 8 through a wiring component (not illustrated) such as an aluminum wire. The wiring component need not always be an aluminum wire. The electrical connection may be established by, for example, a metal wire such as a copper wire, or a metal plate using a bonding material such as solder. The main terminals 7 and the control terminals 6 are integrated by molding while being exposed from the molding portion 8.

The plurality of (four) main terminals 7 extend in a right-left direction (a first direction) that is a direction parallel to the base portion 11 of the heat sink 13, and are exposed from the molding portion 8. Specifically, the two main terminals 7 are linearly formed to extend in a left direction from a left end of the molding portion 8, and the remaining two main terminals 7 are linearly formed to extend in a right direction from a right end of the molding portion 8. A second main surface (a lower surface) of the main terminal 7, which is on the opposite side of a first main surface (an upper surface) thereof, faces the heat sink 13, and the first main surface (upper surface) of the main terminal 7 faces the opposite side of the heat sink 13 (upward).

Here, when a current flowing through a power module is larger, the lead frame 3 including the main terminals 7 and the control terminals 6 is often thickened in view of the current density. Thus, bending the thick lead frame 3 by the terminal-shaping machining increases the press tonnage, which creates a concern about upsizing of a facility and decrease in the productivity.

In Embodiment 1, the second main surface (lower surface) of the main terminal 7, which is on the opposite side of the first main surface (upper surface) thereof, faces the heat sink 13, and the first main surface (upper surface) of the main terminal 7 faces the opposite side of the heat sink 13 (upward) as described above. In other words, since the main terminals 7 with a larger terminal cross-sectional area are formed to extend in a horizontal direction with respect to the molding portion 8, the terminal-shaping machining on the first main surface and the second main surface of each of the main terminals 7 is unnecessary. Thus, the area of the first main surface and the second main surface can be increased. Furthermore, only the control terminals 6 with a smaller terminal cross-sectional area are subjected to the terminal-shaping machining as necessary. Thus, upsizing the facility is unnecessary, and the productivity will be increased.

Furthermore, connecting the bus bars 10 to the main terminals 7 can shorten the main terminals 7 without needing to lengthen the main terminals 7 in view of heat dissipation. The area of the lead frame 3 including the main terminals 7 can be reduced by the shortened length of the main terminals 7. This enables retrieval of shapes of multiple lead frames 3 from one lead frame (multiple lead frames 3), which can improve the productivity. Alternatively, the area of the lead frame 3 inside the power module 202 can be increased by the shortened length of the main terminals 7, while the area of the lead frame 3 including the main terminals 7 remains the same. This can improve the flexibility in designing the placement of the semiconductor chips 1 and electric wiring, and improve heat dissipation.

### [Modification of Embodiment 1]

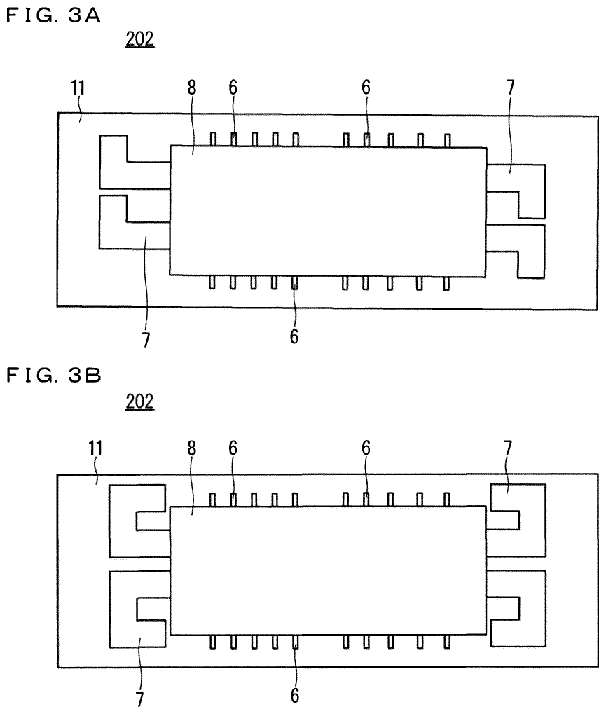

Next, a modification of Embodiment 1 will be described. FIG. 3 (a) and FIG. 3 (b) are top views of the power module 202 according to the modification of Embodiment 1.

The main terminals 7 may be L-shaped in a top view as illustrated in FIG. 3 (a), or may be U-shaped in a top view as illustrated in FIG. 3 (b). The shape of the main terminal 7 is not limited to these, but can be designed without restraint. Forming the main terminals 7 into such shapes can reduce the stress to be applied to an interface between the main terminals 7 and the molding portion 8 when the bus bars 10 are the connected to the main terminals 7. Furthermore, when vibrations occur during product use, the stress to be applied to the interface between the main terminals 7 and the molding portion 8 can be reduced. Thus, resistance to vibration of the product will be improved.

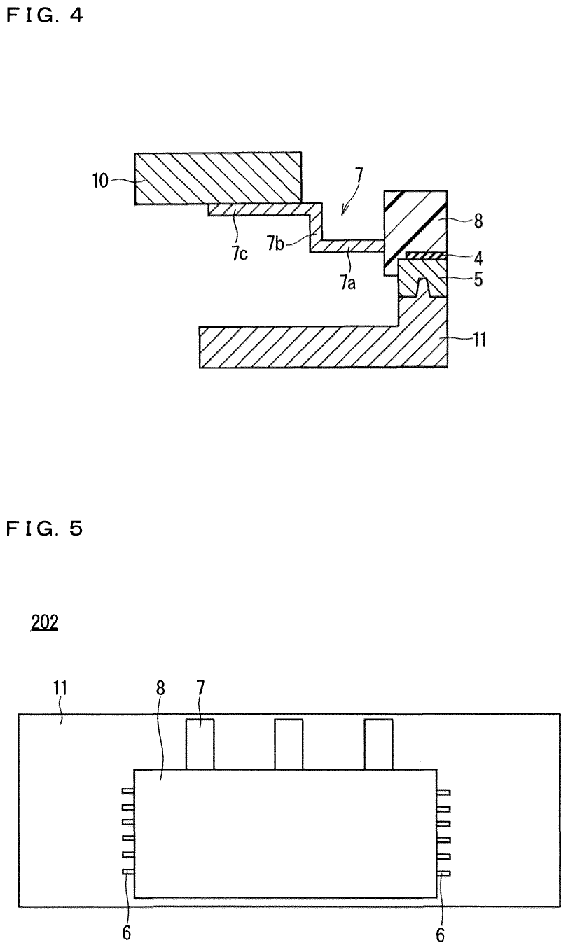

FIG. 4 is a cross-sectional view illustrating a connection between the main terminal 7 and the bus bar 10 which are included in the power module 202 according to a modification of Embodiment 1. As illustrated in FIG. 4, the main terminal 7 may be cranked in a cross-sectional view. Specifically, the main terminal 7 includes a first parallel portion 7a exposed from the molding portion 8 in a first direction that is a direction parallel to the base portion 11 of the heat sink 13, a first vertical portion 7b extending in a second direction that is a direction vertical to the first parallel portion 7a, and a second parallel portion 7c extending from the first vertical portion 7b in the first direction. The bus bar 10 is connected to a first main surface of the second parallel portion 7c of the main terminal 7.

As illustrated in FIG. 4, bending the main terminal 7 in the terminal-shaping machining allows the bent portion to have an elasticity function. Thus, when the bus bars 10 are the connected to the main terminals 7, the stress to be applied to the interface between the main terminals 7 and the molding portion 8 can be reduced. Similarly, when vibrations occur during product use, the stress to be applied to the interface between the main terminals 7 and the molding portion 8 can be reduced. Thus, resistance to vibration of the product will be improved. Although the shape of the main terminal 7 in FIG. 4 requires bending, for example, the single bus bar 10 with a large area can be connected in a stable state to two of the main terminals 7 because the second parallel portion 7c extends in the horizontal direction.

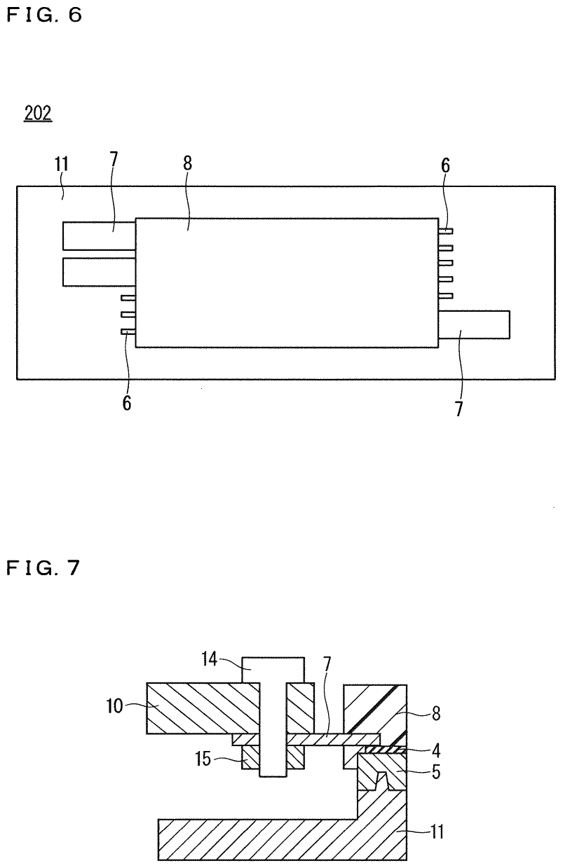

As illustrated in FIG. 2, the power module 202 according to Embodiment 1 has a structure in which the main terminals 7 are disposed on two sides of the molding portion 8 and the control terminals 6 are disposed on the other two sides in a top view. The placement of the main terminals 7 and the control terminals 6 is not limited to this. FIGS. 5 and 6 are top views of the power module 202 according to modifications of Embodiment 1. The placement of the main terminals 7 and the control terminals 6 can be designed without restraint. As illustrated in FIG. 5, the main terminals 7 may be disposed on one of the sides and the control terminals 6 may be disposed on the other two sides. As illustrated in FIG. 6, each side may have a different mix of the main terminals 7 and the control terminals 6. Thus, disposing the main terminals 7 and the control terminals 6 on a plurality of sides in the power module 202 brings an advantage of increasing the design flexibility of electric wiring (e.g., an aluminum wire) inside the power module 202.

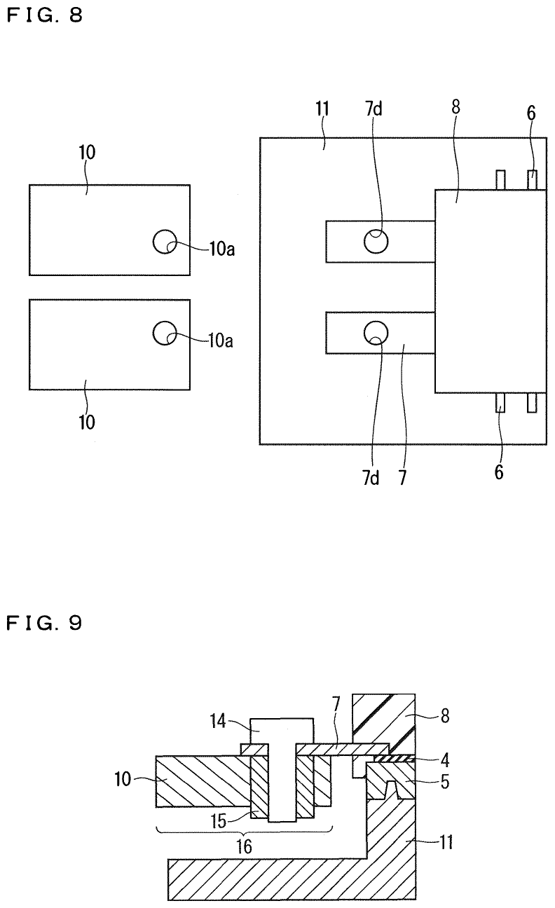

FIG. 7 is a cross-sectional view illustrating a screwing connection between the main terminal 7 and the bus bar 10 which are included in the power module 202 according to a modification of Embodiment 1. FIG. 8 is a top view of screwing connections between the main terminals 7 and the bus bars 10 which are included in the power module 202 according to the modification of Embodiment 1.

As illustrated in FIG. 7, a method of connecting the bus bar 10 to the main terminal 7 using a screw 14 and a nut 15 by screwing enables the simplest connection with better productivity. The screwing will be described. As illustrated in FIG. 8, each of the main terminals 7 is provided with a threaded bore 7d, and each of the bus bars 10 is provided with a threaded bore 10a at a position corresponding to the threaded bore 7d. The screwing is performed by tightening the nut 15 on a shaft of the screw 14 with the shaft of the screw 14 being inserted into the threaded bore 10a and the threaded bore 7d.

The screwing connection may be established after disposing the bus bars 10 on the main terminals 7, disposing the screws 14 on the bus bars 10, and disposing the nuts 15 under the main terminals 7. Alternatively, the screwing connection may be established after disposing the bus bars 10 under the main terminals 7, disposing the screws 14 on the main terminals 7, and disposing the nuts 15 under the bus bars 10. Although the productivity decreases, the screwing is possible after changing places between the screws 14 and the nuts 15 in each layout.

FIG. 9 is a cross-sectional view illustrating a screwing connection between the main terminal 7 and a nut-inserted bus bar 16 which are included in the power module 202 according to a modification of Embodiment 1. Moreover, connecting, using the nut-inserted bus bar 16 obtained by inserting the nut 15 into the bus bar 10, the main terminal 7 to the nut-inserted bus bar 16 by screwing is possible as illustrated in FIG. 9 to connect the bus bar 10 with better productivity.

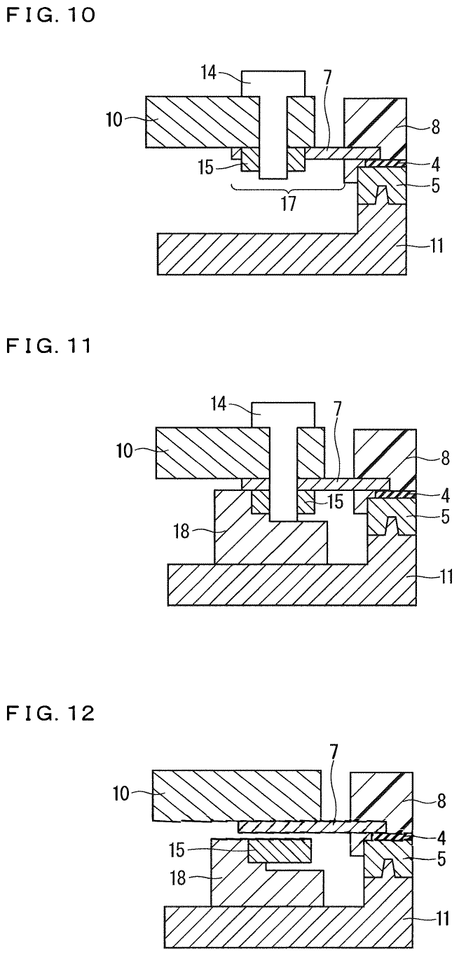

FIG. 10 is a cross-sectional view illustrating a screwing connection between a nut-inserted main terminal 17 and the bus bar 10 which are included in the power module 202 according to a modification of Embodiment 1. FIG. 11 is a cross-sectional view illustrating a screwing connection between the main terminal 7 and the bus bar 10 in which a screwing auxiliary component 18 included in the power module 202 according to a modification of Embodiment 1 is disposed.

Similarly, connecting, using the nut-inserted main terminal 17 obtained by inserting the nut 15 into the main terminal 7, the bus bar 10 to the nut-inserted main terminal 17 by screwing is possible as illustrated in FIG. 10. In this case, the lead frame 3 obtained by inserting the nuts 15 into the main terminals 7 is used to perform the molding. Alternatively, after the molding and the terminal-shaping machining, the nut 15 is inserted into the main terminal 7. In any of these methods, the screwing connection between the nut-inserted main terminal 17 and the bus bar 10 is possible.

When the main terminal 7 is formed to extend in the horizontal direction and the bus bar 10 is screwed with the main terminal 7, inserting the screwing auxiliary component 18 as illustrated in FIG. 11 enables the screwing connection between the main terminal 7 and the bus bar 10 with better productivity.

Furthermore, disposing the screwing auxiliary component 18 and connecting the bus bar 10 to the main terminal 7 by screwing can control a displacement to be applied to the main terminal 7 in the screwing, and reduce the stress to be applied to the interface between the molding portion 8 and the main terminal 7 in the screwing. This brings an advantage of being able to reduce a rejection rate.

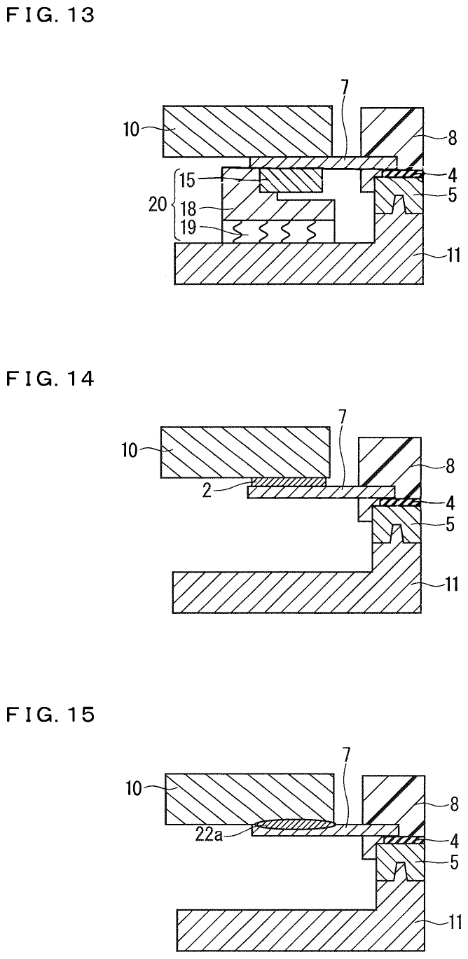

FIG. 12 is a cross-sectional view illustrating a position relationship between the main terminal 7 and the screwing auxiliary component 18 which are included in the power module 202 according to a modification of Embodiment 1. FIG. 13 is a cross-sectional view illustrating a position relationship between the main terminal 7 and an elasticity-function screwing auxiliary component 20 which are included in the power module 202 according to a modification of Embodiment 1.

As illustrated in FIG. 12, the main terminal 7 and the screwing auxiliary component 18 on which the nut 15 is disposed do not always have zero clearance in a height direction as a position relationship because of, for example, tolerances of the components and warpage of the molding portion 8. In other words, a state between which the main terminal 7 and the screwing auxiliary component 18 is one of a state with a clearance (a displacement) as illustrated in FIG. 12 and a state in which the main terminal 7 and the screwing auxiliary component 18 interfere with each other. When the displacement to be applied in connecting the bus bar 10 to the main terminal 7, that is, the clearance between the main terminal 7 and the screwing auxiliary component 18 is large, a large stress is applied to the interface between the molding portion 8 and the main terminal 7 in screwing. This creates a concern about stripping or cracks on the interface. Thus, reducing the clearance between the main terminal 7 and the screwing auxiliary component 18 is preferable.

As illustrated in FIG. 13, using the elasticity-function screwing auxiliary component 20 obtained by disposing an elastic material 19 between the screwing auxiliary component 18 and the base portion 11 can establish the connection with much better productivity, and allows a large current to flow through the power module 202.

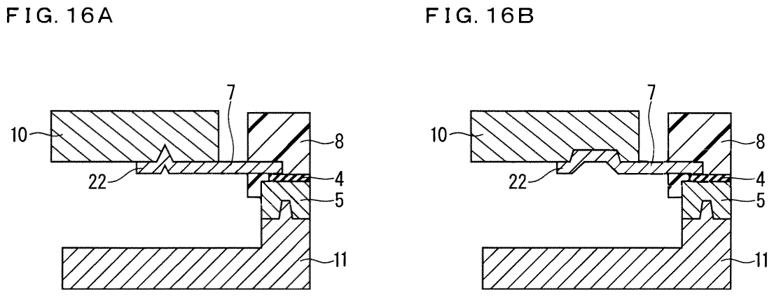

FIG. 14 is a cross-sectional view illustrating a connection between the main terminal 7 and the bus bar 10 via solder 2 which are included in the power module 202 according to a modification of Embodiment 1. FIG. 15 is a cross-sectional view illustrating a welding connection between the main terminal 7 and the bus bar 10 which are included in the power module 202 according to a modification of Embodiment 1. FIG. 16 is a cross-sectional view illustrating a crimping connection between the main terminal 7 and the bus bar 10 which are included in the power module 202 according to a modification of Embodiment 1.

Here, the main terminal 7 and the bus bar 10 may be connected not only by screwing but also by any connection method, for example, by the connection using a bonding material such as the solder 2 as illustrated in FIG. 14, by the welding connection as illustrated in FIG. 15, or by the crimping connection as illustrated in FIG. 16. Any of these connection methods can create sufficient connection strength, stably reduce the contact electrical resistance and the contact thermal resistance, and increase a contact area between the bus bar 10 and the main terminal 7. Thus, the temperature rise in the main terminal 7 during product use can be suppressed. Here, a reference numeral 22a in FIG. 15 denotes a welded portion.

A connection method obtained by combining some of the connection methods such as the screwing and the crimping can also be used. Combination of the connection methods can improve the connection strength, stably reduce the contact electrical resistance and the contact thermal resistance, and increase the contact area between the bus bar 10 and the main terminal 7 more than those when only one type of the methods is used. Thus, the temperature rise in the main terminal 7 during product use can be further suppressed.

### [Other Modifications]

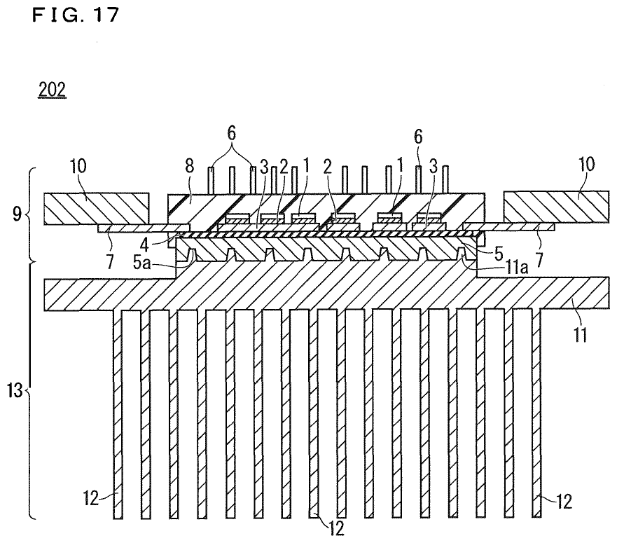

FIGS. 17 to 19 are cross-sectional views of the power module 202 according to a modification of Embodiment 1. FIG. 1 illustrates an example of employing, as the heat sink 13, a crimped heat sink obtained by integrating the base portion 11 with the plurality of radiating fins 12 through crimping. The base portion 11 is processed by, for example, machining, die casting, forging, or extrusion, and is made of aluminum or an aluminum alloy. The radiating fins 12, which are made of a plate of, for example, aluminum or an aluminum alloy, can make processability and heat dissipation compatible.

The materials of the base portion 11 and the radiating fins 12 are not limited to aluminum, but may be combinations of different materials. For example, the radiating fins 12 made of a copper-based plate with thermal conductivity higher than that of an aluminum-based material in view of heat dissipation capacity improve the heat dissipation capacity greater than that of the aluminum-based material.

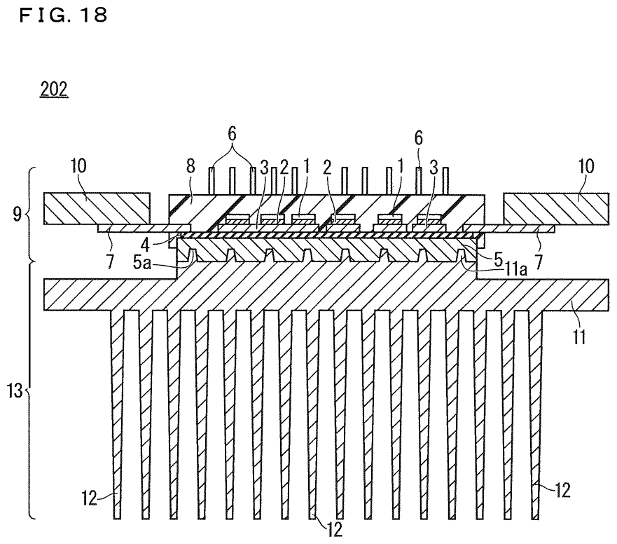

Furthermore, the heat sink 13 is not limited to the crimped heat sink, but may be an extruded heat sink fabricated by extrusion as illustrated in FIG. 17, a machined heat sink fabricated by machining, a forged heat sink fabricated by forging, or a die cast heat sink fabricated by die casting as illustrated in FIG. 18.

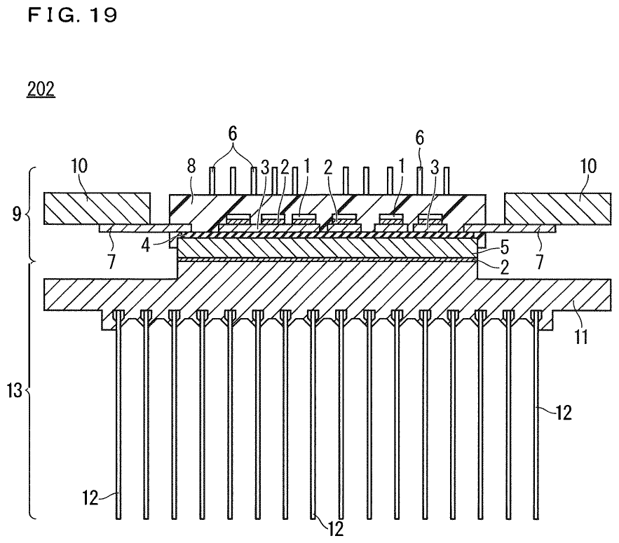

The power module 202 may have a structure obtained by integrating the module base 5 with the heat sink 13 through a bonding material such as the solder 2 and an adhesive, as illustrated in FIG. 19. The module base 5 can be integrated with the heat sink 13 by combination of a plurality of methods, for example, using the crimping and a bonding material.

The module base 5 is processed by, for example, machining, die casting, forging, or extrusion, and is made of aluminum or an aluminum alloy. The material of the module base 5 is not limited to aluminum but a copper-based plate with thermal conductivity higher than that of an aluminum-based material, which improves the heat dissipation capacity much greater than that of the aluminum-based material.

The semiconductor chips 1 may be made of silicon or a wide bandgap semiconductor, such as silicon carbide or gallium nitride.

Materials of the lead frame 3 and the bus bars 10 are preferably a copper-based material or an aluminum-based material in view of electric resistivity and processability. As long as the materials are metals, the limitation is unnecessary.

### [Advantages]

As described above, the power module 202 in Embodiment 1 includes: the semiconductor chip 1; the lead frame 3 on one surface of which the semiconductor chip 1 is mounted; the module base 5 on one surface of which the lead frame 3 is disposed; the main terminal 7 that is a part of the lead frame 3; the molding portion 8 sealing the semiconductor chip 1, the lead frame 3, and the module base 5 such that the main terminal 7 is exposed; the heat sink 13 integrated with the other surface of the module base 5 which is exposed from the molding portion 8; and the bus bar 10 connected to the first main surface of the main terminal 7 or the second main surface on an opposite side of the first main surface, wherein the second main surface of the main terminal 7 faces the heat sink 13, and the first main surface of the main terminal 7 faces an opposite side of the heat sink 13.

Furthermore, a method for manufacturing the power module 202 includes a process (a) of connecting the bus bar 10 to the first main surface or the second main surface of the main terminal 7 by screwing, bonding, or crimping.

Since the terminal-shaping machining on the first main surface and the second main surface of the main terminal 7 is unnecessary, the area of the first main surface and the second main surface can be increased. This enables connection of the bus bar 10 to the main terminal 7 in the heat sink integrated power module 202. Thus, the temperature rise in the main terminal 7 can be suppressed. This consequently allows a large current to flow through the power module 202.

Since the bus bar 10 is connected to the first main surface or the second main surface of the main terminal 7 through the screw 14 and the nut 15, the bus bar 10 can be connected to the main terminal 7 in a simple method with better productivity.

Furthermore, the heat sink 13 includes the base portion 11 integrated with the other surface of the module base 5, and the plurality of radiating fins 12 protruding on the opposite side of the module base 5 with respect to the base portion 11, and the main terminal 7 extends in a first direction that is a direction parallel to the base portion 11 of the heat sink 13, the main terminal 7 being exposed from the molding portion 8.

Since the terminal-shaping machining on the first main surface and the second main surface of the main terminal 7 is unnecessary, the area of the first main surface and the second main surface can be increased. Furthermore, only the control terminals 6 with a smaller terminal cross-sectional area are subjected to the terminal-shaping machining as necessary. Thus, upsizing the facility is unnecessary, and the productivity of the power module will be increased.

Furthermore, the main terminal 7 includes the first parallel portion 7a exposed from the molding portion 8 in a first direction that is a direction parallel to the base portion 11 of the heat sink 13, the first vertical portion 7b extending in a second direction that is a direction vertical to the first parallel portion 7a, and the second parallel portion 7c extending from the first vertical portion 7b in the first direction, and the bus bar 10 is connected to the second parallel portion 7c of the main terminal 7.

Thus, when the bus bars 10 are the connected to the main terminals 7, the stress to be applied to the interface between the main terminals 7 and the molding portion 8 can be reduced. Similarly, when vibrations occur during product use, the stress to be applied to the interface between the main terminals 7 and the molding portion 8 can be reduced. Thus, resistance to vibration of the product will be improved.

Furthermore, the fitting portion 5a is formed on the other surface of the module base 5, the fitted portion 11a into which the fitting portion 5a can be fitted is formed on a surface of the base portion 11 of the heat sink 13, the surface being closer to the module base 5, and the heat sink 13 is integrated with the module base 5, with the fitting portion 5a being fitted into the fitted portion 11a.

Thus, the integration in an ambient temperature process is possible. Since the facility is neither upsized nor complicated, the productivity will be improved.

### Embodiment 2

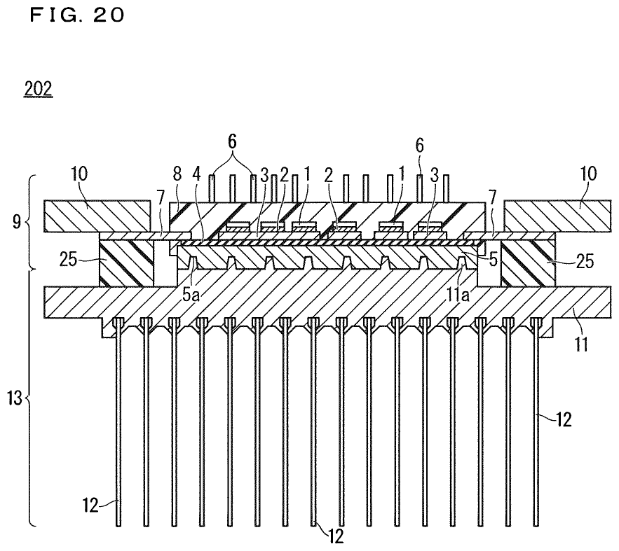

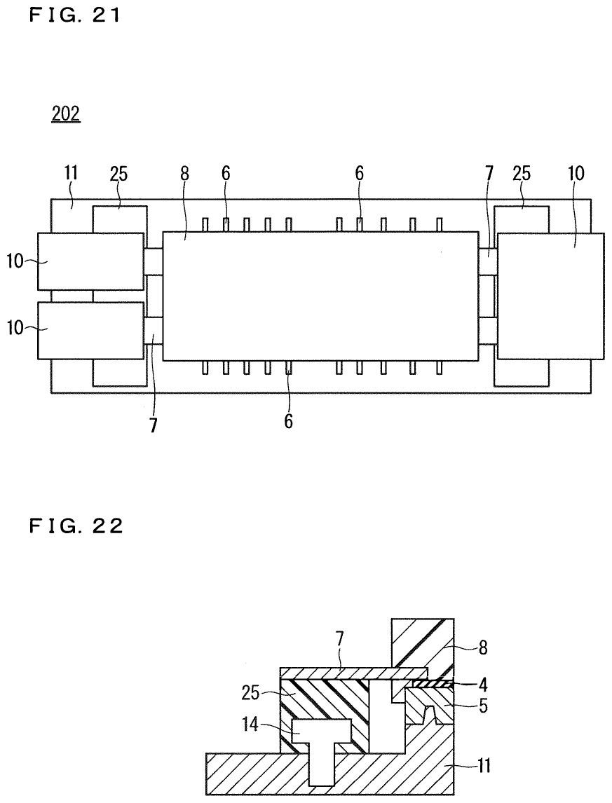

Next, the power module 202 according to Embodiment 2 will be described. FIG. 20 is a cross-sectional view of the power module 202 according to Embodiment 2. FIG. 21 is a top view of the power module 202 according to Embodiment 2. In Embodiment 2, the same reference numerals are assigned to the same constituent elements described in Embodiment 1, and the description thereof will be omitted.

As illustrated in FIGS. 20 and 21, the power module 202 according to Embodiment 2 further includes terminal blocks 25 (a displacement-controlling structural component), unlike Embodiment 1. The terminal blocks 25 are fixed on the perimeter of the base portion 11 of the heat sink 13, and are disposed between the main terminals 7 and the base portion 11.

Although the bus bars 10 are disposed on the main terminals 7 and the terminal blocks 25 are disposed under the main terminals 7 in FIG. 20, except this, the bus bars 10 may be disposed under the main terminals 7, and the terminal blocks 25 may be disposed further under the bus bars 10. The terminal blocks 25 are made of a resin in view of processability and insulating properties. The terminal blocks 25 need not always be made of a resin but may be made of a metal.

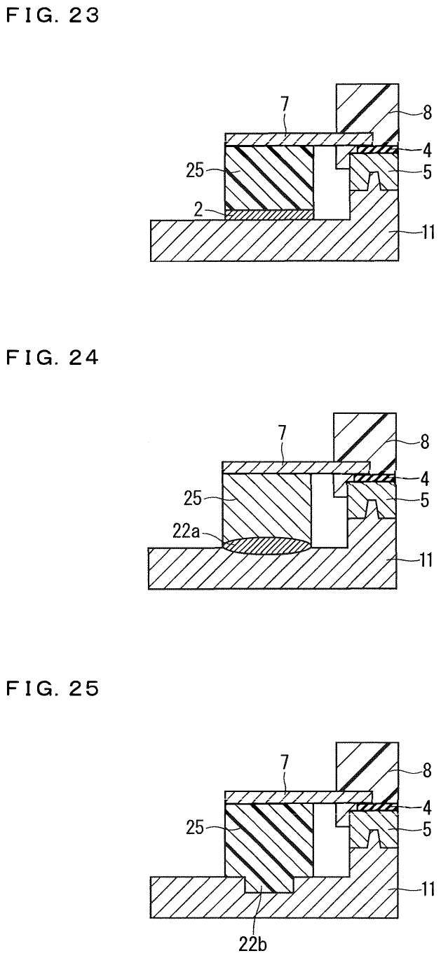

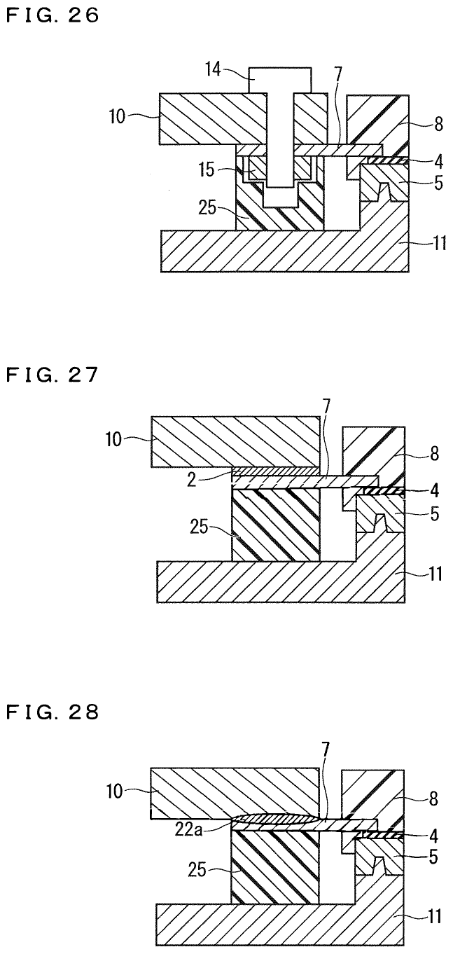

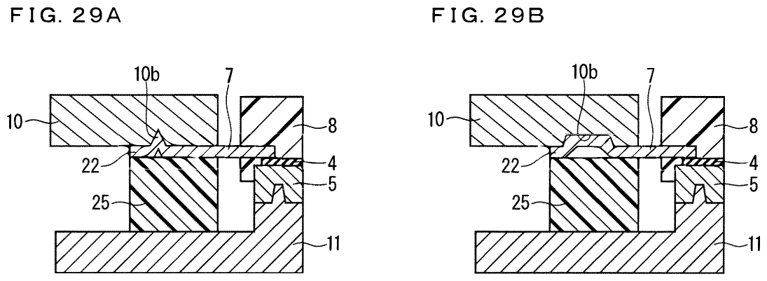

Next, connections between the terminal blocks 25 and the base portion 11 and connections between the main terminals 7 and the bus bars 10 will be described. FIG. 22 is a cross-sectional view illustrating a screwing connection between the terminal block 25 and the heat sink 13 which are included in the power module 202 according to Embodiment 2. FIG. 23 is a cross-sectional view illustrating a connection between the terminal block 25 and the heat sink 13 via the solder 2 which are included in the power module 202 according to a modification of Embodiment 2. FIG. 24 is a cross-sectional view illustrating a welding connection between the terminal block 25 and the heat sink 13 which are included in the power module 202 according to a modification of Embodiment 2. FIG. 25 is a cross-sectional view illustrating a crimping connection between the terminal block 25 and the heat sink 13 which are included in the power module 202 according to a modification of Embodiment 2. FIG. 26 is a cross-sectional view illustrating a screwing connection between the main terminal 7 and the bus bar 10 which are included in the power module 202 according to a modification of Embodiment 2. FIG. 27 is a cross-sectional view illustrating a connection between the main terminal 7 and the bus bar 10 via the solder 2 which are included in the power module 202 according to a modification of Embodiment 2. FIG. 28 is a cross-sectional view illustrating a welding connection between the main terminal 7 and the bus bar 10 which are included in the power module 202 according to a modification of Embodiment 2. FIG. 29 is a cross-sectional view illustrating a crimping connection between the main terminal 7 and the bus bar 10 which are included in the power module 202 according to a modification of Embodiment 2.

Here, the terminal block 25 may be fixed to the base portion 11 of the heat sink 13 by any connection method, for example, by the screwing connection as illustrated in FIG. 22, by the connection using a bonding material such as the solder 2 as illustrated in FIG. 23, by the welding connection as illustrated in FIG. 24, or by the crimping connection as illustrated in FIG. 25. Furthermore, the main terminal 7 and the bus bar 10 may be connected by any connection method, for example, by the screwing connection as illustrated in FIG. 26, by the connection using a bonding material such as the solder 2 as illustrated in FIG. 27, by the welding connection as illustrated in FIG. 28, or by the crimping connection as illustrated in FIG. 29. Here, the reference numeral 22a in each of FIGS. 24 and 28 denotes a welded portion, and a reference numeral 22b in FIG. 25 denotes a crimped portion.

Since the power module 202 further includes the terminal blocks 25, the displacement to be applied to the main terminals 7 can be controlled, and the stress to be applied to the interface between the molding portion 8 and the main terminals 7 can be reduced. Thus, a rejection rate in a process of connecting the bus bars 10 to the main terminals 7 can be reduced. Furthermore, a clearance between the terminal block 25 and the main terminal 7 or the bus bar 10 can be controlled during product use. This can reduce the displacement in vibrations. Thus, the stress to be applied to the interface between the molding portion 8 and the main terminals 7 can be reduced, and the resistance to vibration of the product will be improved.

As illustrated in FIG. 26, disposing the nut 15 on the terminal block 25 fixed to the base portion 11 of the heat sink 13, and connecting the bus bar 10 to the main terminal 7, or fixing the terminal block 25 in which the nut 15 is disposed to the base portion 11 and connecting the bus bar 10 to the main terminal 7 can implement a screwing structure in a simple method with better productivity.

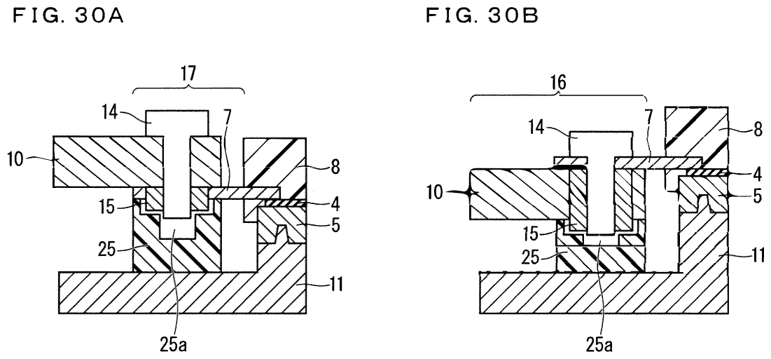

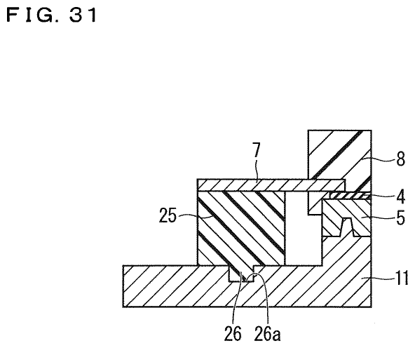

FIG. 30 (a) and FIG. 30 (b) are cross-sectional views of screwing connections each between the main terminal 7 and the bus bar 10, using the nut-inserted main terminal 17 and the nut-inserted bus bar 16, respectively, all of which are included in the power module 202 according to a modification of Embodiment 2. As illustrated in FIG. 30 (a), the screwing connection is established by providing a space 25a for the nut 15 in the terminal block 25, using the nut-inserted main terminal 17, and disposing the bus bar 10 on the nut-inserted main terminal 17. Alternatively, the screwing connection may be established by providing the space 25a for the nut 15 in the terminal block 25, using the nut-inserted bus bar 16, and disposing the main terminal 7 on the nut-inserted bus bar 16, as illustrated in FIG. 30 (b).

The structure illustrated in FIG. 27 can implement a soldering structure in a simple method with better productivity. A simple method such as the welding as illustrated in FIG. 28 or brazing can implement a welding structure with better productivity.

As illustrated in FIG. 29 (a) and FIG. 29 (b), the bus bar 10 is connected to the main terminal 7 by providing a crimping space 10b in the bus bar 10 and applying pressure from the bus bar 10 to the main terminal 7 that is formed to fit the shape of the space 10b, as a crimping connection structure. The crimping connection structure can be implemented in this simple method with better productivity. The space 10b is triangular in a cross-sectional view of FIG. 29 (a), and the space 10b is trapezoidal in a cross-sectional view of FIG. 29 (b). Although pressure is applied from the bus bar 10 to the main terminal 7 in FIG. 29, except this, the bus bar 10 may be crimped onto the main terminal 7 by providing a space in the main terminal 7 and applying pressure from the main terminal 7 to the bus bar 10.

FIG. 31 is a cross-sectional view illustrating the placement of the terminal block 25 with a positioning structure which is included in the power module 202 according to a modification of Embodiment 2.

As illustrated in FIG. 31, forming a positioning groove 26a in the base portion 11 of the heat sink 13 and forming, on the terminal block 25, a protruding positioning portion 26 that can be fitted into the groove 11b can simplify a process of attaching the terminal block and will improve the productivity.

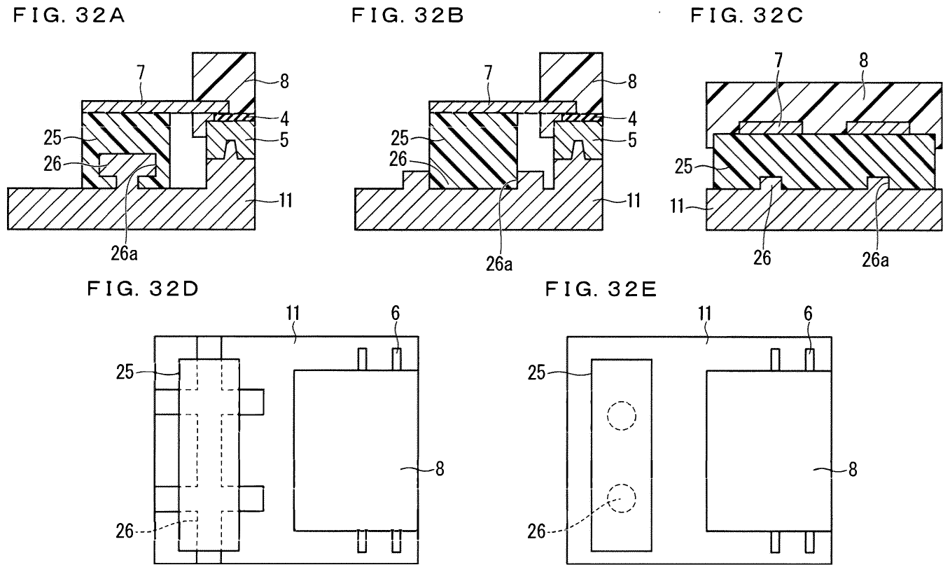

FIG. 32 (a) and FIG. 32 (b) are cross-sectional views illustrating the placement of the terminal block 25 with the positioning structure which is included in the power module 202 according to a modification of Embodiment 2, and FIG. 32 (c) is a side view thereof. FIG. 32 (d) and FIG. 32 (e) are top views illustrating the placement of the terminal block 25 with the positioning structure which is included in the power module 202 according to the modification of Embodiment 2.

The positioning portion 26 of the terminal block 25 may have any structure as long as the structure can determine a position of the terminal block 25 at least in one direction or more, for example, the structures illustrated in FIG. 32 (a) to FIG. 32 (e), not limited to the structure illustrated in FIG. 31. Specifically, the positioning groove 26a may be formed in the terminal block 25, and the positioning portion 26 that is T-shaped in a cross-sectional view may be formed on the base portion 11 as illustrated in FIG. 32 (a). Alternatively, the whole lower end of the terminal block 25 may be used as the positioning portion 26, and the base portion 11 may have the groove 26a into which the positioning portion 26 can be fitted, as illustrated in FIG. 32 (b). Alternatively, two of the protruding positioning portions 26 may be formed on the base portion 11, and two of the grooves 26a may be formed in the terminal block 25 as illustrated in FIG. 32 (c). Alternatively, the positioning portion 26 formed on the base portion 11 may have a shape of two connected crosses in a top view as illustrated in FIG. 32 (d). Alternatively, the two positioning portions 26 formed on the base portion 11 may be cylindrical as illustrated in FIG. 32 (e).

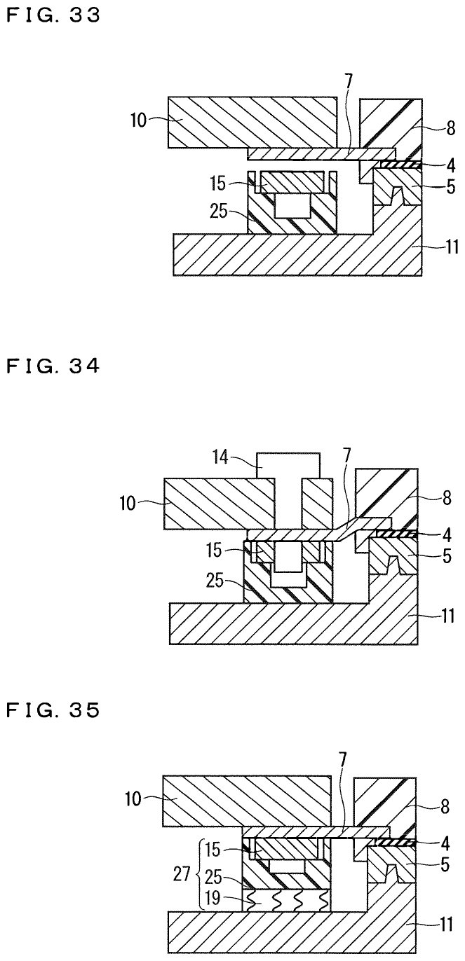

Next, a clearance between the main terminal 7 and the terminal block 25 will be described. FIG. 33 is a cross-sectional view illustrating the clearance between the main terminal 7 and the terminal block 25 which are included in the power module 202 according to a modification of Embodiment 2. FIG. 34 is a cross-sectional view illustrating a screwing connection between the main terminal 7 and the bus bar 10 in the presence of a clearance between the main terminal 7 and the terminal block 25 which are included in the power module 202 according to a modification of Embodiment 2. FIG. 35 is a cross-sectional view illustrating a clearance between the main terminal 7 and the terminal block 25 when an elasticity-function terminal block 27 included in the power module 202 according to a modification of Embodiment 2 is used.

As illustrated in FIG. 33, the main terminal 7 and the terminal block 25 do not always have zero clearance in the height direction as a position relationship because of, for example, the tolerances of the components and the warpage of the molding portion 8. In other words, a state between the main terminal 7 and the terminal block 25 is one of a state with a clearance (a displacement) as illustrated in FIG. 33 and a state in which the main terminal 7 and the terminal block 25 interfere with each other. When the displacement to be applied in connecting the bus bar 10 to the main terminal 7, that is, the clearance between the main terminal 7 and the terminal block 25 is large, a large stress is applied to the interface between the molding portion 8 and the main terminal 7 in screwing as illustrated in FIG. 34. This creates a concern about stripping or cracks on the interface. Thus, reducing the clearance between the main terminal 7 and the terminal block 25 is preferable.

Thus, the elasticity-function terminal block 27 which is obtained by disposing the elastic material 19 between the terminal block 25 and the base portion 11 as illustrated in FIG. 35 allows a large current to flow through the power module 202 with much better productivity.

Although the terminal block 25 with the nut 15 is used and the bus bar 10 is connected to the main terminal 7 by screwing in Embodiment 2, except this, using the elasticity-function terminal block 27 can produce similar advantages even when the bus bar 10 is connected to the main terminal 7 through soldering, welding, or crimping. Although the main terminal 7 extending in the horizontal direction is described, the main terminal 7 may have the shape as illustrated in FIG. 4. In this case, the terminal block 25 is disposed between the second parallel portion 7c and the base portion 11 or between the bus bar 10 disposed under the second parallel portion 7c and the base portion 11.

As described above, the power module 202 according to Embodiment 2 further includes the terminal block 25 fixed to the base portion 11 of the heat sink 13 and disposed between the base portion 11 and the main terminal 7 or the bus bar 10.

Furthermore, a method for manufacturing the power module 202 includes: the process (a) of connecting the bus bar 10 to the first main surface or the second main surface of the main terminal 7 by screwing, bonding, or crimping; and a process (b) of fixing the terminal block 25 to the base portion 11 of the heat sink 13 with the terminal block 25 being in contact with the main terminal 7 or the bus bar 10.

Thus, the displacement to be applied to the main terminals 7 can be controlled with better productivity. When the bus bars 10 are the connected to the main terminals 7, the stress to be applied to the interface between the main terminals 7 and the molding portion 8 can be reduced. Similarly, during product use, the clearance between the terminal block 25 and the main terminal 7 or the bus bar 10 can be controlled. The stress to be applied to the interface between the main terminals 7 and the molding portion 8 can be reduced during vibrations. Thus, resistance to vibration of the product will be improved.

Since the terminal block 25 is in contact with the main terminal 7 or the bus bar 10, the power module vibrates integrally with the terminal block 25 during vibrations. Thus, the resistance to vibration of the product will be further improved.

The power module 202 further includes the elastic material 19 disposed between the terminal block 25 and the base portion 11. Even in the presence of a clearance between the terminal block 25 and the main terminal 7 or the bus bar 10 in the height direction, the elastic material 19 enables the terminal block 25 to be in contact with the main terminal 7 or the bus bar 10.

### Embodiment 3

Next, the power module 202 according to Embodiment 3 will be described. Since the cross-sectional view and the top view of the power module 202 according to Embodiment 3 are identical to those according to Embodiment 2, Embodiment 3 will be described with reference to FIGS. 20 and 21. In Embodiment 3, the same reference numerals are assigned to the same constituent elements described in Embodiments 1 and 2, and the description thereof will be omitted.

As illustrated in FIGS. 20 and 21, not only the bus bars 10 but also the terminal blocks 25 fixed to the heat sink 13 are connected to the main terminals 7 in Embodiment 3. Although the bus bars 10 are disposed on the main terminals 7 and the terminal blocks 25 are disposed under the main terminals 7 in FIG. 20, except this, the bus bars 10 may be disposed under the main terminals 7, and the terminal blocks 25 may be disposed further under these bus bars 10.

Here, the terminal blocks 25 may be fixed to the base portion 11 of the heat sink 13 by any connection method, for example, by the screwing connection as illustrated in FIG. 22, by the connection using a bonding material such as the solder 2 as illustrated in FIG. 23, by the welding connection as illustrated in FIG. 24, or by the crimping connection as illustrated in FIG. 25.

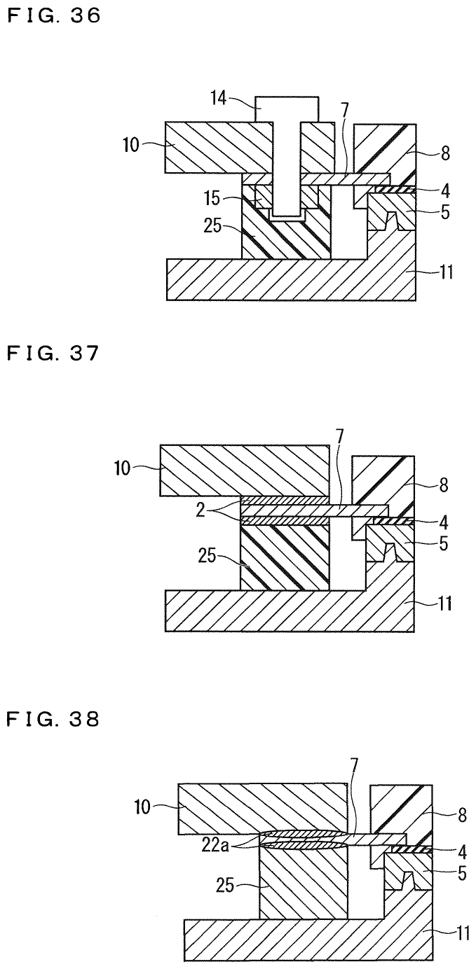

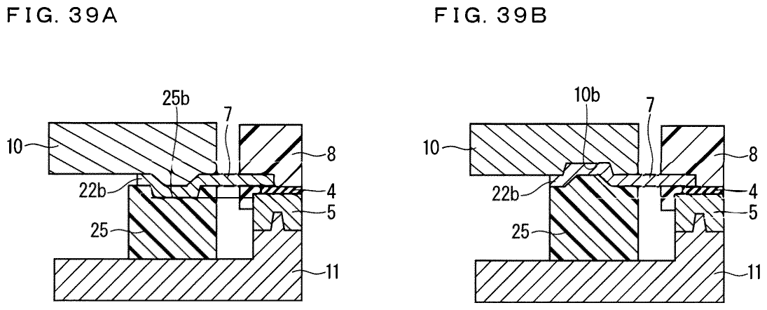

FIG. 36 is a cross-sectional view illustrating a screwing connection between the main terminal 7, the bus bar 10, and the terminal block 25 which are included in the power module 202 according to Embodiment 3. FIG. 37 is a cross-sectional view illustrating connections by the solder 2 between the main terminal 7, the bus bar 10, and the terminal block 25 which are included in the power module 202 according to Embodiment 3. FIG. 38 is a cross-sectional view illustrating welding connections between the main terminal 7, the bus bar 10, and the terminal block 25 which are included in the power module 202 according to Embodiment 3. FIG. 39 (a) and FIG. 39 (b) are cross-sectional views each illustrating a crimping connection between the main terminal 7, the bus bar 10, and the terminal block 25 which are included in the power module 202 according to Embodiment 3.

The main terminal 7, the bus bar 10, and the terminal block 25 may be connected by any connection method, for example, by the screwing connection as illustrated in FIG. 36, by the connections using a bonding material such as the solder 2 as illustrated in FIG. 37, by the welding connections as illustrated in FIG. 38, or by the crimping connection as illustrated in FIG. 39 (a) and FIG. 39 (b). These can control the displacement to be applied to the main terminals 7 with better productivity, and the stress to be applied to the interface between the molding portion 8 and the main terminals 7 can be reduced. Thus, the rejection rate in a process of connecting the bus bars 10 to the main terminals 7 can be reduced.

The nut 15 may be fixed to the terminal block 25 in the screwing structure by any method, such as inserting the nut 15 in molding the terminal block 25, press fitting the nut 15 after molding the terminal block 25, or bonding the nut 15 via a bonding material.

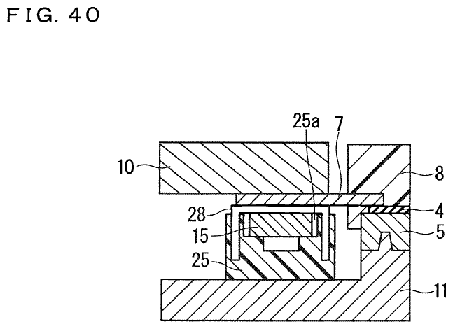

FIG. 40 is a cross-sectional view illustrating the terminal block 25 including a nut fall-off proof metal component 28 which is included in the power module 202 according to Embodiment 3. As illustrated in FIG. 40, it is possible to provide the space 25a for disposing the nut 15 in the terminal block 25, dispose the nut 15 in the space 25a, dispose, on the nut 15, the nut fall-off proof metal component 28 that is U-shaped in a cross-sectional view, and insert the metal component 28 into the terminal block 25 with upward movement of the nut 15 being restricted by the metal component 28, so that the power module 202 with much better productivity can be implemented.

Connecting the main terminal 7 and the bus bar 10 to the terminal block 25 by providing a crimping space 25b in the terminal block 25 and applying pressure from the bus bar 10 to the main terminal 7 and the terminal block 25 as illustrated in FIG. 39 (a) or by providing the crimping space 10b in the bus bar 10 and applying pressure from the bus bar 10 to the main terminal 7 and the terminal block 25 which are formed to correspond to the shape of the space 10b as illustrated in FIG. 39 (b) can implement the crimping connection structure in a simple method with better productivity. Since the main terminal 7 and the bus bar 10 are connected to the terminal block 25 fixed to the heat sink 13 integrated with the power module unit 9, the stress to be applied to the main terminals 7 by vibrations occurring during product use can be reduced. Thus, resistance to vibration of the product will be improved.

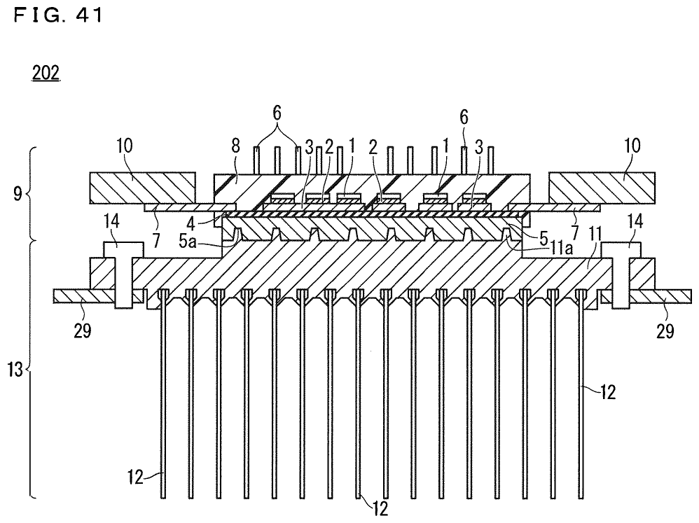

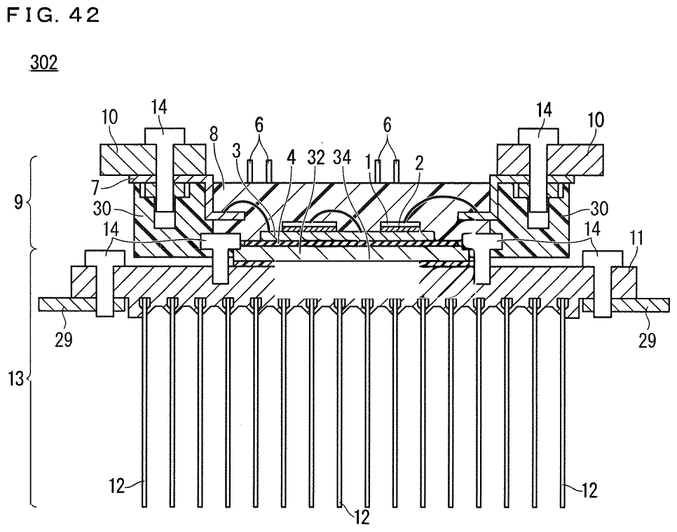

Here, a reason why the resistance to vibration during product use is improved will be described. FIG. 41 is a cross-sectional view illustrating a state of the power module 202 according to Embodiment 3 during product use. FIG. 42 is a cross-sectional view illustrating a typical power module 302 during product use.

As illustrated in FIG. 41, the heat sink 13 is fixed to a unit frame 29 of a product, for example, by screwing during the product use. In the typical power module 302 as illustrated in FIG. 42, terminal blocks 30 are disposed inside the power module 302, and the power module unit 9 and the heat sink 13 are fixed through the screws 14 with a heat dissipating component 34 such as thermal conductive grease being interposed between the power module unit 9 and the heat sink 13, that is, between a metal component 32 disposed under the insulating component 4 and the base portion 11. Thus, although the unit frame 29 and the heat sink 13 vibrate in a fixed state when the product vibrates, the unit frame 29 and the heat sink 13 vibrate separately from components (the main terminals 7 and the bus bars 10) connected to the heat sink 13 through the heat dissipating component 34 in an upper portion of the power module unit 9. Consequently, excessive stress caused by the vibrations is applied between the main terminals 7 and the bus bars 10, and a malfunction such as a terminal break may occur.

Since the power module 202 according to Embodiment 3 as illustrated in FIG. 41 includes the terminal blocks 25 and the main terminals 7 which are fixed to the heat sink 13, and the bus bars 10 connected to the main terminals 7, the power module 202 fixed to the unit frame 29 and the connected portions integrally vibrate. This can reduce the stress to be applied to the interface between the molding portion 8 and the main terminals 7 when the product vibrates, and will improve the resistance to vibration of the product.

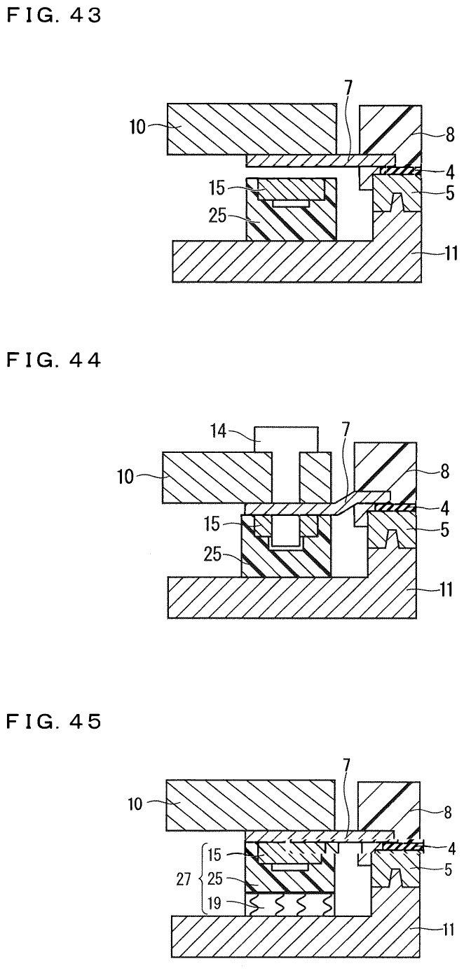

FIG. 43 is a cross-sectional view illustrating a clearance between the main terminal 7 and the terminal block 25 which are included in the power module 202 according to a modification of Embodiment 3. FIG. 44 is a cross-sectional view illustrating a screwing connection between the main terminal 7, the bus bar 10, and the terminal block 25 in the presence of a clearance between the main terminal 7 and the terminal block 25 which are included in the power module 202 according to Embodiment 3. FIG. 45 is a cross-sectional view illustrating a clearance between the main terminal 7 and the terminal block 25 when the elasticity-function terminal block 27 included in the power module 202 according to Embodiment 3 is used.

As illustrated in FIG. 43, when the main terminal 7, the bus bar 10, and the terminal block 25 are connected, the main terminal 7 and the terminal block in which the nut 15 is disposed do not always have zero clearance in the height direction as a position relationship because of, for example, the tolerances of the components and the warpage of the molding portion 8.

In other words, a state between the main terminal 7 and the terminal block 25 in which the nut 15 is disposed is one of a state with a clearance (a displacement) as illustrated in FIG. 43 and a state in which the main terminal 7 and the terminal block 25 interfere with each other. When the displacement to be applied in connecting the bus bar 10 to the main terminal 7, that is, the clearance between the main terminal 7 and the terminal block 25 in which the nut 15 is disposed is large, a large stress is applied to the interface between the molding portion 8 and the main terminal 7 in screwing as illustrated in FIG. 44. This creates a concern about stripping or cracks on the interface. Thus, reducing the clearance between the main terminal 7 and the terminal block 25 in which the nut 15 is disposed is preferable.

Here, using the elasticity-function terminal block 27 which is obtained by disposing the elastic material 19 between the base portion 11 and the terminal block 25 in which the nut 15 is disposed as illustrated in FIG. 45 allows a large current to flow through the power module 202 with much better productivity.

Although the terminal block 25 with the nut 15 is used and the bus bar 10 is connected to the main terminal 7 by screwing in Embodiment 3, except this, using the elasticity-function terminal block 27 even when the bus bar 10 is connected to the main terminal 7 through soldering, welding, or crimping can produce similar advantages.

Although the main terminal 7 extending in the horizontal direction is described, the main terminal 7 may have the shape as illustrated in FIG. 4. In this case, the terminal block 25 is disposed between the second parallel portion 7c and the base portion 11 or between the bus bar 10 disposed under the second parallel portion 7c and the base portion 11.

As described above, since not only the bus bars 10 but also the terminal blocks 25 fixed to the heat sink 13 are connected to the main terminals 7 in Embodiment 3, the stress to be applied to the main terminals 7 by vibrations occurring during product use can be reduced, and resistance to vibration of the product will be improved.

### Embodiment 4

Embodiment 4 will describe a power conversion device using the power module 202 according to Embodiments 1 to 3. Although this use of the power module 202 according to Embodiments 1 to 3 is not limited to specific power conversion devices, Embodiment 4 will describe use of the power module 202 according to Embodiments 1 to 3 in a three-phase inverter.

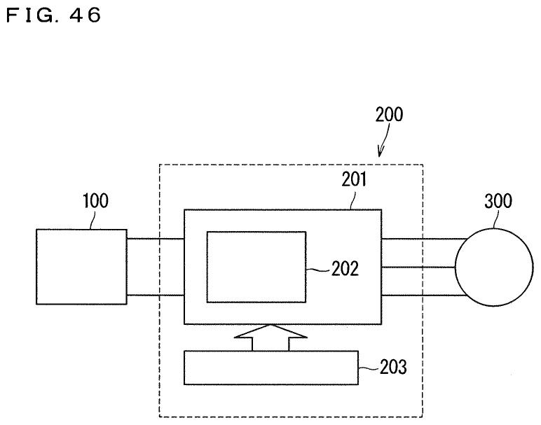

FIG. 46 is a block diagram illustrating a configuration of a power conversion system using the power conversion device according to Embodiment 4.

The power conversion system illustrated in FIG. 46 includes a power supply 100, a power conversion device 200, and a load 300. The power supply 100, which is a DC power supply, supplies a DC power to the power conversion device 200. The power supply 100 may include various components such as a DC system, a solar battery, or a rechargeable battery, and a rectifying circuit connected to an AC system or an AC/DC converter. The power supply 100 may include a DC/DC converter which converts the DC power output from the DC system into a predetermined power.

The power conversion device 200, which is a three-phase inverter connected between the power supply 100 and the load 300, converts the DC power supplied from the power supply 100 into the AC power to supply the AC power to the load 300. As illustrated in FIG. 46, the power conversion device 200 includes a main conversion circuit 201 that converts the DC power to output the AC power, and a control circuit 203 that outputs, to the main conversion circuit 201, a control signal for controlling the main conversion circuit 201.

The load 300 is a three-phase electrical motor driven by the AC power supplied from the power conversion device 200. The load 300 is not limited to specific use but is an electrical motor mounted on various types of electrical devices. Thus, the load 300 is used as the electrical motor for, for example, a hybrid car, an electrical car, a rail vehicle, an elevator, or air-conditioning equipment.

The power conversion device 200 will be described in detail hereinafter. The main conversion circuit 201 includes switching elements (not illustrated) and freewheeling diodes (not illustrated). Switching of the switching element causes the DC power supplied from the power supply 100 to be converted into the AC power. The main conversion circuit 201 then supplies the AC power to the load 300. The specific circuit configuration of the main conversion circuit 201 is of various types. The main conversion circuit 201 according to Embodiment 4 is a three-phase full-bridge circuit having two levels, and can include six switching elements and six freewheeling diodes anti-parallel connected to the respective switching elements. The power module 202 according to any one of Embodiments 1 to 3 is used as at least one of the switching elements and the freewheeling diodes in the main conversion circuit 201. The six switching elements form three pairs of upper and lower arms in each pair of which the two switching elements are serially connected to each other. The three pairs of upper and lower arms form the respective phases (U-phase, V-phase, and W-phase) of the full-bridge circuit. Output terminals of the respective pairs of upper and lower arms, i.e., three output terminals of the main conversion circuit 201 are connected to the load 300.

The main conversion circuit 201 includes a drive circuit (not illustrated) for driving each of the switching elements. The drive circuit may be embedded in the power module 202 or provided separately from the power module 202. The drive circuit generates driving signals for driving the switching elements of the main conversion circuit 201, and supplies the driving signals to control electrodes of the switching elements of the main conversion circuit 201. Specifically, the drive circuit outputs, to the control electrode of each of the switching elements in accordance with the control signal from the control circuit 203 to be described hereinafter, the driving signal for switching the switching element to an ON state and the driving signal for switching the switching element to an OFF state. When the switching element is kept in the ON state, the driving signal is a voltage signal (an ON signal) higher than or equal to a threshold voltage of the switching element. When the switching element is kept in the OFF state, the driving signal is a voltage signal (an OFF signal) lower than or equal to the threshold voltage of the switching element.

The control circuit 203 controls the switching elements of the main conversion circuit 201 so that a desired power is supplied to the load 300. Specifically, the control circuit 203 calculates a time (ON time) when each of the switching elements of the main conversion circuit 201 needs to enter the ON state, based on the power which needs to be supplied to the load 300. For example, the control circuit 203 can control the main conversion circuit 201 by performing PWM control for modulating the ON time of the switching elements in accordance with the voltage which needs to be output. Then, the control circuit 203 outputs a control instruction (a control signal) to the drive circuit included in the main conversion circuit 201 so that the drive circuit outputs the ON signal to the switching element which needs to enter the ON state and outputs the OFF signal to the switching element which needs to enter the OFF state at each time. The drive circuit outputs the ON signal or the OFF signal as the driving signal to the control electrode of each of the switching elements in accordance with this control signal.

In the power conversion device according to Embodiment 4, the power module 202 according to Embodiments 1 to 3 is used as each of the switching elements and the freewheeling diodes in the main conversion circuit 201. Thus, the productivity can be improved.

Although Embodiment 4 describes an example of using the power module 202 according to Embodiments 1 to 3 in a three-phase inverter having two levels, the power module 202 according to Embodiments 1 to 3 can be used not only in the three-phase inverter but also in various power converters. Although Embodiment 4 describes the power conversion device having the two levels, the power conversion device may have three or multiple levels. The power module 202 according to Embodiments 1 to 3 may be used in a single-phase inverter when the power is supplied to a single-phase load. Moreover, the power module 202 according to Embodiments 1 to 3 can be used in a DC/DC converter or an AC/DC converter when the power is supplied to, for example, a DC load.

The load of the power conversion device using the power module 202 according to Embodiments 1 to 3 is not limited to the electrical motor as described above. The power conversion device can also be used as a power-supply device of an electrical discharge machine, a laser beam machine, an induction heat cooking device, or a non-contact power feeding system, and can be further used as a power conditioner of, for example, a solar power system or an electricity storage system.

Although this disclosure is described in detail, the description is in all aspects illustrative and does not restrict the disclosure. Therefore, numerous modifications and variations that have not yet been exemplified can be devised.

Embodiments can be combined without restraint, and appropriately modified or omitted.

A summary of various aspects of the present disclosure will be hereinafter described as Appendixes.

### APPENDIX 1

A power module, comprising:
a semiconductor element;
a frame on one surface of which the semiconductor element is mounted;
a module base on one surface of which the frame is disposed;
a main terminal that is a part of the frame;
a molding portion sealing the semiconductor element, the frame, and the module base such that the main terminal is exposed;
a heat sink including a base portion integrated with an other surface of the module base which is exposed from the molding portion, and a plurality of radiating fins protruding on an opposite side of the module base with respect to the base portion;
an external terminal connected to a first main surface of the main terminal or a second main surface on an opposite side of the first main surface; and
a displacement-controlling structural component fixed on the base portion of the heat sink and disposed between the base portion and the main terminal or the external terminal,
wherein the second main surface of the main terminal faces the heat sink, and
the first main surface of the main terminal faces an opposite side of the heat sink.

### APPENDIX 2

The power module according to appendix 1, wherein the external terminal is connected to the first main surface or the second main surface of the main terminal through a screw and a nut.

### APPENDIX 3

The power module according to appendix 1, wherein the main terminal extends in a first direction that is a direction parallel to the base portion of the heat sink, the main terminal being exposed from the molding portion.

### APPENDIX 4

The power module according to appendix 1,
wherein the main terminal includes a first parallel portion exposed from the molding portion in a first direction that is a direction parallel to the base portion of the heat sink, a first vertical portion extending in a second direction that is a direction vertical to the first parallel portion, and a second parallel portion extending from the first vertical portion in the first direction,
and the external terminal is connected to the second parallel portion of the main terminal.

### APPENDIX 5

The power module according to appendix 1,
wherein the displacement-controlling structural component is in contact with the main terminal or the external terminal.

### APPENDIX 6

The power module according to appendix 5, further comprising
an elastic material disposed between the displacement-controlling structural component and the base portion.

### APPENDIX 7

The power module according to appendix 3,
wherein an fitting portion is formed on the other surface of the module base,
a fitted portion into which the fitting portion can be fitted is formed on a surface of the base portion of the heat sink, the surface being closer to the module base, and
the heat sink is integrated with the module base, with the fitting portion being fitted into the fitted portion.

### APPENDIX 8

The power module according to appendix 4,
wherein an fitting portion is formed on the other surface of the module base,
a fitted portion into which the fitting portion can be fitted is formed on a surface of the base portion of the heat sink, the surface being closer to the module base, and
the heat sink is integrated with the module base, with the fitting portion being fitted into the fitting portion.

### APPENDIX 9

A method of manufacturing the power module according to appendix 1, the method comprising the steps of:
(a) connecting the external terminal to the first main surface or the second main surface of the main terminal by screwing, bonding, or crimping; and
(b) fixing the displacement-controlling structural component to the base portion of the heat sink with the displacement-controlling structural component being in contact with the main terminal or the external terminal.

### APPENDIX 10

A power conversion device, comprising:
a main conversion circuit to convert an input power into a power to be output, the main conversion circuit including the power module according to appendix 1; and
a control circuit to output, to the main conversion circuit, a control signal for controlling the main conversion circuit.

### EXPLANATION OF REFERENCE SIGNS

1 semiconductor chip, 3 lead frame, 5 module base, 5a fitting portion, 7 main terminal, 7a first parallel portion, 7b first vertical portion, 7c second parallel portion, 8 molding portion, 10 bus bar, 11 base portion, 11a fitted portion, 12 radiating fin, 13 heat sink, 14 screw, 15 nut, 16 nut-inserted bus bar, 17 nut-inserted main terminal, 19 elastic material, 25 terminal block, 27 elasticity-function terminal block, 200 power conversion device, 201 main conversion circuit, 202 power module, 203 control circuit.

1. A power module, comprising:
a semiconductor element;
a frame on one surface of which the semiconductor element is mounted;
a module base on one surface of which the frame is disposed;
a main terminal that is a part of the frame;
a molding portion sealing the semiconductor element, the frame, and the module base such that the main terminal is exposed;
a heat sink including a base portion integrated with an other surface of the module base which is exposed from the molding portion, and a plurality of radiating fins protruding on an opposite side of the module base with respect to the base portion;
an external terminal connected to a first main surface of the main terminal or a second main surface on an opposite side of the first main surface; and
a displacement-controlling structural component fixed on a perimeter of the base portion on a surface of the base portion closer to the module base, and disposed between the perimeter and the main terminal or the external terminal,
wherein the second main surface of the main terminal faces the heat sink, and
the first main surface of the main terminal faces an opposite side of the heat sink.

2.-10. (canceled)

11. The power module according to claim 1,
wherein the main terminal is smaller in terminal cross-sectional area than the external terminal.

12. The power module according to claim 1,
wherein the displacement-controlling structural component is screwed with the perimeter of the base portion on the surface of the base portion closer to the module base.

13. The power module according to claim 1,
wherein the displacement-controlling structural component is disposed only on the perimeter of the base portion on the surface of the base portion closer to the module base.

14. The power module according to claim 1,
wherein the external terminal is connected to the first main surface or the second main surface of the main terminal through a screw and a nut.

15. The power module according to claim 1,
wherein the main terminal extends in a first direction that is a direction parallel to the base portion of the heat sink, the main terminal being exposed from the molding portion.

16. The power module according to claim 1,
wherein the main terminal includes a first parallel portion exposed from the molding portion in a first direction that is a direction parallel to the base portion of the heat sink, a first vertical portion extending in a second direction that is a direction vertical to the first parallel portion, and a second parallel portion extending from the first vertical portion in the first direction, and
the external terminal is connected to the second parallel portion of the main terminal.

17. The power module according to claim 1,
wherein the displacement-controlling structural component is in contact with the main terminal or the external terminal.

18. The power module according to claim 17, further comprising
an elastic material disposed between the displacement-controlling structural component and the base portion.

19. The power module according to claim 15,
wherein an fitting portion is formed on the other surface of the module base,
a fitted portion into which the fitting portion can be fitted is formed on a surface of the base portion of the heat sink, the surface being closer to the module base, and
the heat sink is integrated with the module base, with the fitting portion being fitted into the fitted portion.

20. The power module according to claim 16,
wherein an fitting portion is formed on the other surface of the module base,
a fitted portion into which the fitting portion can be fitted is formed on a surface of the base portion of the heat sink, the surface being closer to the module base, and
the heat sink is integrated with the module base, with the fitting portion being fitted into the fitting portion.

21. A method of manufacturing the power module according to claim 1, the method comprising the steps of:
(a) connecting the external terminal to the first main surface or the second main surface of the main terminal by screwing, bonding, or crimping; and
(b) fixing the displacement-controlling structural component to the base portion of the heat sink with the displacement-controlling structural component being in contact with the main terminal or the external terminal.

22. A power conversion device, comprising:
a main conversion circuit to convert an input power into a power to be output, the main conversion circuit including the power module according to claim 1; and
a control circuit to output, to the main conversion circuit, a control signal for controlling the main conversion circuit.
